(19) United States
(12) Patent Application Publication
(10) Pub. No.: US 2007/0236253 A1
(43) Pub. Date: Oct. 11, 2007

(54) SEMICONDUCTOR INTEGRATED CIRCUIT

(75) Inventors: Fumihiko Tachibana, Kawasaki-Shi (JP); Mototsugu Hamada, Yokohama-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/695,771

(22) Filed: Apr. 3, 2007

(30) Foreign Application Priority Data
Apr. 5, 2006 (JP) 2006-104015

(51) Int. Cl. H03K 19/094

(52) U.S. Cl. 326/83

(57) ABSTRACT

A semiconductor integrated circuit comprising: a logic section having a plurality of first transistors; a second transistor, having source and drain electrodes connected between a first reference voltage line and a first reference voltage line side terminal of the logic section, and having a gate electrode to which a control signal for controlling whether to supply a power source voltage to the logic section is inputted; a third transistor having a source and drain electrode connected between an output terminal of the logic section and a second reference voltage line, wherein the third transistor turns off when the second transistor turns on, and turns on when the second transistor turns off; and a control section, connected to a gate electrode of the third transistor, and performing on/off control of the third transistor.

### CROSS REFERENCE TO RELATED APPLICATIONS

This application is based upon and claims benefit of priority under 35 USC 119 from the Japanese Patent Application No. 2006-104015, filed on Apr. 5, 2006, the entire contents of which are incorporated herein by reference.

### BACKGROUND OF THE INVENTION

1. Field of the Invention

The present invention relates to a semiconductor integrated circuit.

2. Related Art

As device miniaturization progresses, the gate oxide film of transistor has been increasingly slimmed down. This thinned gate oxide film causes gate leak current to increase, thus increasing power consumption.

As a technique for reducing the leak current, there has been known a multithreshold CMOS (hereinafter referred to as an MT-CMOS) circuit. The MT-CMOS circuit uses a high threshold transistor and a low threshold transistor. The logic section of gate circuit is constituted of a low threshold transistor; and between the logic section of one or more gate circuits, and the power source line or the ground line, there is inserted a high threshold switch transistor. On/off control of the switch transistor is performed by an enable signal.

When such a configuration is used, the switch transistor turns on during operation, whereby power source voltage is applied to the logic section of gate circuit, thus allowing high-speed operation. Also, when the switch transistor turns off during standby, the leak path extending from the power source line to the ground line is cut off, thus making it possible to suppress the leak current of gate circuit.

Also, there has been a boosted gate MOS (hereinafter referred to as a BGMOS) circuit having a configuration similar to that of MT-CMOS circuit, and having a thickened gate oxide film of switch transistor. However, in these circuits, the logic section of all the gate circuits is connected to the high threshold switch transistor; and thus the element formation area may increase.

As another technique for reducing the leak current, there has also proposed a circuit called a selective multithreshold (a Selective-MT, hereinafter simply an SMT) circuit. In this circuit, a gate circuit constituted of a high threshold transistor is used in a path other than the critical path, which has a relatively large timing margin. Meanwhile, in the critical path, there is used a gate circuit constituted of: a logic section constituted of a low threshold transistor; a switch transistor constituted of a high threshold transistor, which is inserted between the logic section and a ground line; and a pull-up transistor constituted of a high threshold transistor, which is inserted between the output terminal of the logic section and a power source line. On/off control of the switch transistor and pull-up transistor is performed by an enable signal (for example, refer to Japanese Patent Laid-Open No. 2002-9242).

When such a configuration is used, in the gate circuit of critical path, the switch transistor turns on and the pull-up transistor turns off during operation, whereby power source voltage is applied to the logic section, thus allowing high-speed operation. Also, when the switch transistor turns off during standby, the leak path is cut off, thus making it possible to reduce the leak current. Further, when the pull-up transistor turns on, the output of the circuit is fixed at a high level, thus preventing the output from having an indefinite value.

Since a high threshold transistor is used in a path other than the critical path, the leak current can be reduced. Also, the logic section constituted of a low threshold transistor and the gate circuit constituted of the switch transistor and pull-up transistor of a high threshold constitute only one part of the circuit, so the element formation area of the circuit can be reduced, compared to that of the MT-CMOS circuit and BGMOS circuit.

However, in the above described SMT circuit of conventional art, while the gate circuit of critical path is in a standby state, when the pull-up transistor receives a low-level signal, a high voltage is applied thereto, and thus a leak current flows, thereby causing a problem.

### SUMMARY OF THE INVENTION

According to one aspect of the present invention, there is provided a semiconductor integrated circuit comprising:

a logic section having a plurality of first transistors;

a second transistor, having source and drain electrodes connected between a first reference voltage line and a first reference voltage line side terminal of the logic section, and having a gate electrode to which a control signal for controlling whether to supply a power source voltage to the logic section is inputted;

a third transistor having a source and drain electrode connected between an output terminal of the logic section and a second reference voltage line, wherein the third transistor turns off when the second transistor turns on, and turns on when the second transistor turns off; and

a control section, connected to a gate electrode of the third transistor, and performing on/off control of the third transistor.

According to one aspect of the present invention, there is provided a semiconductor integrated circuit comprising:

first and second gate circuits with switch each having:

a logic section having a plurality of first transistors; and

a second transistor, having a source and drain electrode connected between a first reference voltage line and a first reference voltage line side terminal of the logic section, and having a gate electrode to which a control signal for controlling whether to supply a power source voltage to the logic section is inputted,

a third transistor having a source and drain electrode connected between an output terminal of the logic section of the first gate circuit with switch and a second reference voltage line; and

a control section, connected to a gate electrode of the third transistor, and performing on/off control of the third transistor,

wherein an output terminal of the second gate circuit with switch and an input terminal of the first gate circuit with switch are connected to each other.

According to one aspect of the present invention, there is provided a semiconductor integrated circuit comprising:

first and second gate circuits each having:

a logic section having a plurality of first transistors; and

a second transistor having source and drain electrode connected between an output terminal of the logic section and a first reference voltage line,

a third transistor, having source and drain electrode connected between a second reference voltage line and second reference voltage line side terminals of the first and second gate circuits, and having a gate electrode to which a control signal for controlling whether to supply a power source voltage to the first and second gate circuits is inputted; and

a control section, connected to a gate electrode of the second transistor, and performing on/off control of the second transistor so that the second transistor is turned off when the third transistor turns on, and turned on when the third transistor turns off.

### BRIEF DESCRIPTION OF THE DRAWINGS

FIG. 1 is a view illustrating a circuit configuration of a semiconductor integrated circuit according to a first embodiment of the present invention;

FIG. 2 is a view illustrating an exemplary circuit configuration of a logic section of the semiconductor integrated circuit according to the first embodiment and output levels of each gate during standby;

FIG. 3 is a view illustrating an exemplary circuit configuration of a logic section of the semiconductor integrated circuit according to the first embodiment and output levels of each gate during standby;

FIG. 4 is a view illustrating an exemplary circuit configuration of a logic section of the semiconductor integrated circuit according to the first embodiment and output levels of each gate during standby;

FIG. 5 is a view illustrating a circuit configuration of a semiconductor integrated circuit according to a variation of the first embodiment;

FIG. 6 is a view illustrating a circuit configuration of a semiconductor integrated circuit according to a second embodiment of the present invention;

FIG. 7 is a view illustrating an exemplary circuit configuration of a logic section of the semiconductor integrated circuit according to the second embodiment and output levels of each gate during standby;

FIG. 8 is a view illustrating a circuit configuration of a semiconductor integrated circuit according to a variation of the second embodiment of the present invention;

FIG. 9 is a view illustrating a circuit configuration of a semiconductor integrated circuit according to a third embodiment of the present invention;

FIG. 10 is a view illustrating a circuit configuration of a semiconductor integrated circuit according to a fourth embodiment of the present invention;

FIG. 11 is a view illustrating a circuit configuration of a semiconductor integrated circuit according to a fifth embodiment of the present invention.

### DETAILED DESCRIPTION OF THE INVENTION

Hereafter, a semiconductor integrated circuit according to embodiments of the present invention will be described more specifically with reference to the drawings.

### First Embodiment

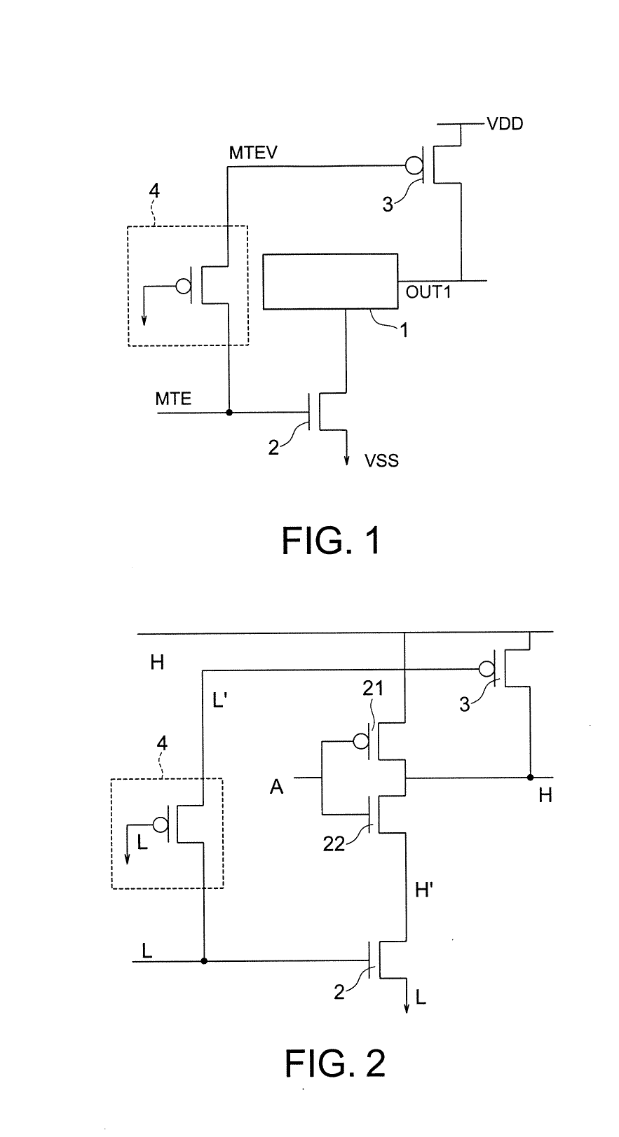

FIG. 1 illustrates a circuit configuration of an SMT gate circuit being a semiconductor integrated circuit according to a first embodiment of the present invention. The SMT gate circuit includes a logic section 1, a switch transistor 2, a pull-up transistor 3 and a pull-up control section 4.

The logic section 1 is constituted of a low threshold transistor. The switch transistor 2 is an NMOS transistor, arranged between the logic section 1 and a ground VSS, and turned on/off by an MT enable signal MTE inputted to a gate electrode thereof. The pull-up transistor 3 is a PMOS transistor which turns on when the switch transistor 2 turns off and thereby fixes the output of the logic section 1 at a high level so as to prevent output logic from becoming indefinite. The threshold of the switch transistor 2 and pull-up transistor 3 is higher than that of the transistor constituting the logic section 1. The signal input terminal of the logic section 1 and the terminal thereof for connection to a power source line are not illustrated here.

The pull-up control section 4 has a PMOS transistor having the gate input thereof fixed at the ground potential VSS. An MT enable signal MTE is inputted to the pull-up control section 4 and then an output MTEV thereof is inputted to the gate electrode of the pull-up transistor 3.

When a high level MT enable signal MTE is inputted to the gate electrode of the switch transistor 2, the switch transistor 2 turns on, and thus the ground potential VSS is applied to the logic section 1, changing the logic section 1 to an operating state. At this time, the pull-up transistor 3 is in an off state, so an output OUT1 of the logic section 1 is outputted from an output terminal thereof (not illustrated).

Meanwhile, when a low level MT enable signal MTE is inputted to the gate electrode of the switch transistor 2, the switch transistor 2 turns off, and thus the leak path of the logic section 1 is cut off, changing the logic section 1 to a standby state. When the low level MT enable signal MTE is inputted to the pull-up control section 4, the output MTEV thereof changes to a potential higher than the low level. This output MTEV is a potential higher than the low level, but sufficient to turn on the pull-up transistor 3 of a threshold Vth3 (VSS<MTEV<VDD−|Vth3|). Accordingly, when the output MTE is inputted to the gate electrode of the pull-up transistor 3, the pull-up transistor 3 turns on and thereby fixes the output OUT1 of the logic section 1 at a high level, preventing output logic from becoming indefinite.

It is known that gate leak current flowing in a transistor increases exponentially with the increase of a voltage applied to the gate electrode thereof. The voltage to be applied to the gate electrode of the pull-up transistor 3 is raised by the pull-up control section 4; thus the voltage is accordingly higher, compared to when a low level MT enable signal MTE is inputted to the gate electrode. Consequently, the gate leak current flowing in the pull-up transistor can be reduced.

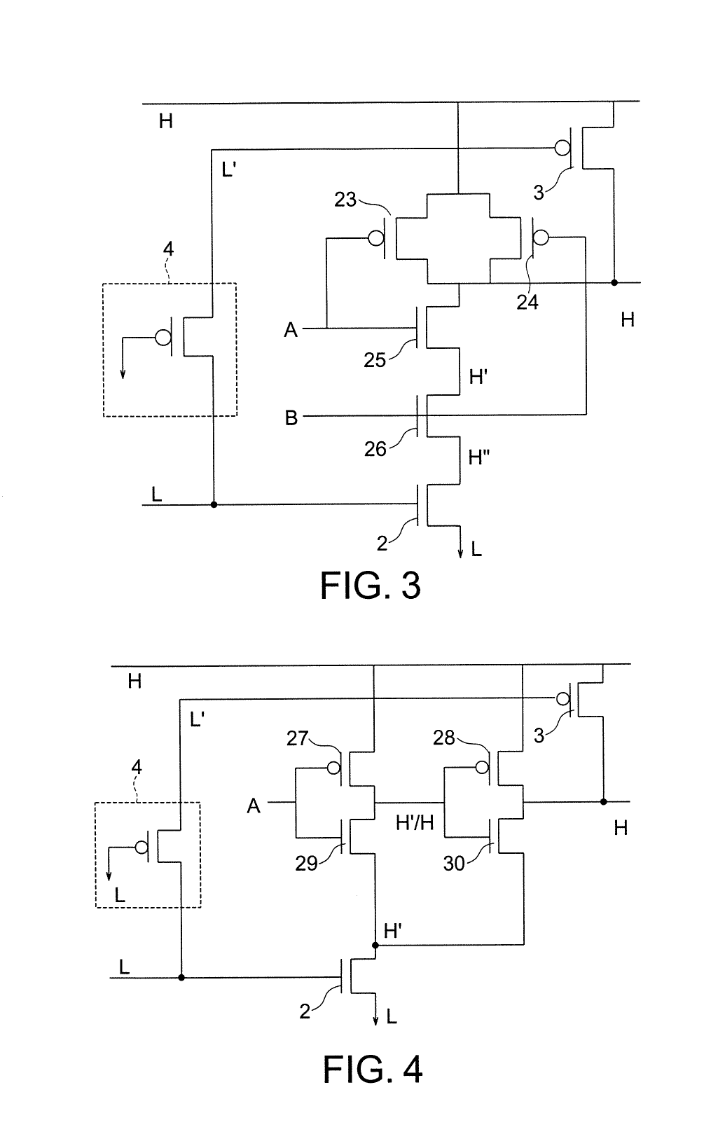

FIGS. 2 to 4 illustrate a circuit configuration in which the logic section 1 is constituted of an inverter, a NAND and a buffer, respectively, and also illustrate output levels of each transistor when a low level MT enable signal MTE is inputted to the gate electrode of the switch transistor 2 and thus the switch transistor 2 turns off, changing the logic section 1 to a standby state. The inverter includes a PMOS transistor 21 and an NMOS transistor 22. The NAND includes PMOS transistors 23 and 24 and NMOS transistors 25 and 26. The buffer includes PMOS transistors 27 and 28 and NMOS transistors 29 and 30. Reference characters “A” and “B” denote the input of the inverter, NAND and buffer. Here, assume that ground potential VSS=L<L′<<H″<H′<H=power source potential VDD. For example, when “A” is high level (H), H′=H−Vth1 where Vth1 is a threshold voltage of each transistor of the logic section 1. H″ has a value slightly lower than H′ and becomes substantially equal thereto as time passes.

When receiving a low level MT enable signal MTE, the output level of the pull-up control section 4 changes to L′, and then this level is inputted to the gate electrode of the pull-up transistor 3. This L′ is sufficient to turn on the pull-up transistor 3 of a threshold Vth3 (L<L′<VDD−|Vth3|). Consequently, the pull-up transistor 3 turns on and thus the output of the logic section 1 is fixed at a high level (H), preventing output logic from becoming indefinite. At this time, the voltage applied to the gate electrode of the pull-up transistor 3 is higher by L′−L, compared to when an MT enable signal MTE of a low level (L) is inputted, and thus the gate leak current of the pull-up transistor 3 is suppressed.

As described above, according to the semiconductor integrated circuit of the first embodiment, the gate leak current flowing in the pull-up transistor while the gate circuit is in a standby state can be suppressed.

In this case, the logic section 1 is not limited to an inverter, NAND and buffer, and may be constituted of another logic circuit.

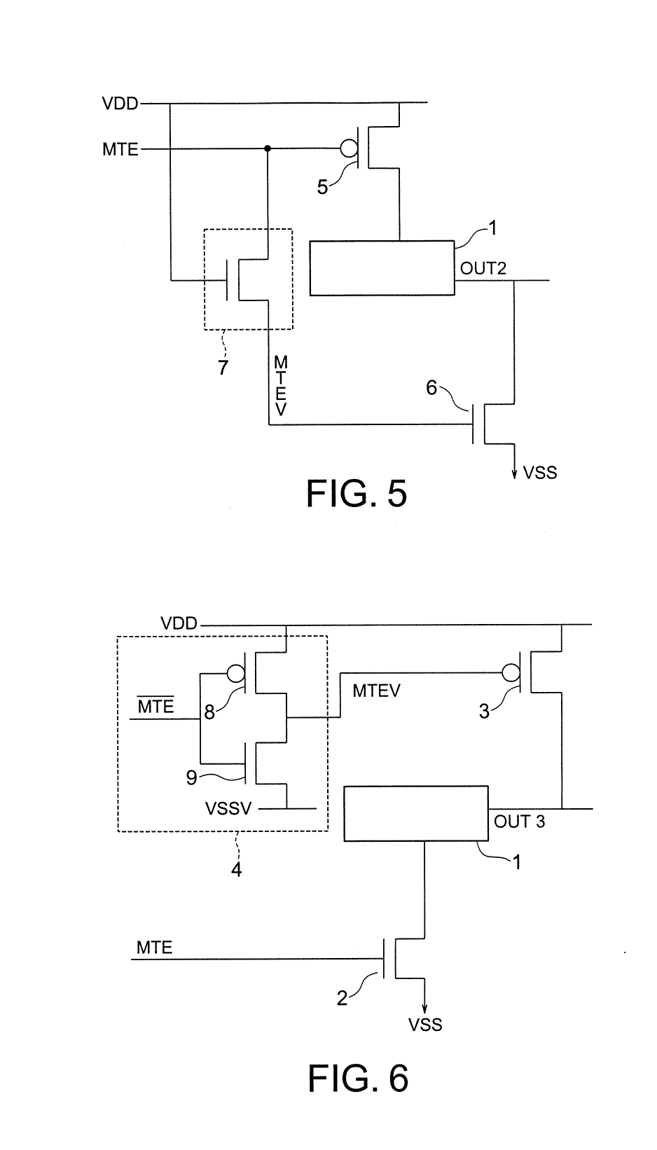

FIG. 5 illustrates a circuit configuration of a SMT gate circuit being a semiconductor integrated circuit according to a variation of the first embodiment. The SMT gate circuit has a logic section 1, a switch transistor 5, a pull-down transistor 6 and a pull-down control section 7.

The logic section 1 is constituted of a low threshold transistor. The switch transistor 5 is a PMOS transistor, arranged between the logic section 1 and a power source VDD, and turned on/off by an MT enable signal MTE inputted to the gate electrode thereof. The pull-down transistor 6 is an NMOS transistor which turns on when the switch transistor 5 turns off and thereby fixes the output of the logic section 1 at a low level so as to prevent output logic from becoming indefinite. The threshold of the switch transistor 5 and pull-down transistor 6 is higher than that of the transistor constituting the logic section 1.

The pull-down control section 7 has an NMOS transistor having the gate input thereof fixed at the power source potential. An MT enable signal MTE is inputted to the pull-down control section 7 and then an output MTEV thereof is inputted to the gate electrode of the pull-down transistor 6.

When a low level MT enable signal MTE is inputted to the gate electrode of the switch transistor 5, the switch transistor 5 turns on, and thus the power source voltage is applied to the logic section 1, changing the logic section 1 to an operating state. At this time, the pull-down transistor 6 is in an off state, so an output OUT2 of the logic section 1 is outputted from an output terminal thereof (not illustrated).

Meanwhile, when a high level MT enable signal MTE is inputted to the gate electrode of the switch transistor 5, the switch transistor 5 turns off, and thus the leak path of the logic section 1 is cut off, changing the logic section 1 to a standby state. When the low level MT enable signal MTE is inputted to the pull-down control section 7, the output MTEV thereof changes to a potential lower than the high level. This output MTEV is a potential lower than the high level, but sufficient to turn on the pull-down transistor 6 of a threshold Vth6 (Vth6<MTEV<VDD). Accordingly, when the output MTEV is inputted to the gate electrode of the pull-down transistor 6, the pull-down transistor 6 turns on and thereby fixes the output OUT2 of the logic section 1 at a low level, preventing output logic from becoming indefinite.

The voltage to be applied to the gate electrode of the pull-down transistor 6 is lowered by the pull-down control section 7; thus the voltage is accordingly lower, compared to when a high level MT enable signal MTE is inputted to the gate electrode. Consequently, the gate leak current flowing in the pull-down transistor 6 can be reduced.

Using the above described configuration, the gate leak current flowing in the pull-down transistor while the gate circuit is in a standby state can be suppressed.

### Second Embodiment

FIG. 6 illustrates a circuit configuration of an SMT gate circuit being a semiconductor integrated circuit according to a second embodiment of the present invention. The SMT gate circuit includes a logic section 1, a switch transistor 2, a pull-up transistor 3 and a pull-up control section 4.

The logic section 1 is constituted of a low threshold transistor. The switch transistor 2 is an NMOS transistor, arranged between the logic section 1 and a ground VSS, and turned on/off by an MT enable signal MTE inputted to the gate electrode thereof. The pull-up transistor 3 is a PMOS transistor which turns on when the switch transistor 2 turns off and thereby fixes the output of the logic section 1 at a high level so as to prevent output logic from becoming indefinite. The threshold of the switch transistor 2 and pull-up transistor 3 is higher than that of the transistor constituting the logic section 1.

The pull-up control section 4 has an inverter circuit arranged between a power source line VDD and a reference voltage line VSSV, and receives an inverted signal of an MT enable signal MTE. An output MTEV thereof is inputted to the gate electrode of the pull-up transistor 3. VSSV is higher than the ground potential VSS and is a sufficient potential to turn on the pull-up transistor 3 of a threshold Vth3 (VSS<VSSV<VDD−|Vth3|). This reference voltage line VSSV is arranged in addition to the ground.

When a high level MT enable signal MTE is inputted to the gate electrode of the switch transistor 2, the switch transistor 2 turns on, and thus the ground voltage is applied to the logic section 1, changing the logic section 1 to an operating state. At this time, the pull-up control section 4 receives a low level signal and thus the PMOS transistor 8 turns on, the NMOS transistor 9 turns off and the output MTEV changes to a high level. This MTEV is inputted to the gate electrode of the pull-up transistor 3 and thus the pull-up transistor 3 turns off. Consequently, an output OUT3 of the logic section 1 is outputted from an output terminal thereof (not illustrated).

Meanwhile, when a low level MT enable signal MTE is inputted to the gate electrode of the switch transistor 2, the switch transistor 2 turns off, and thus the leak path of the logic section 1 is cut off, changing the logic section 1 to a standby state. The pull-up control section 4 receives a high level signal and thus the PMOS transistor 8 turns off, the NMOS transistor 9 turns on and the output MTEV changes to VSSV. When this VSSV is inputted to the gate electrode of the pull-up transistor 3, the pull-up transistor 3 turns on and thereby fixes the output OUT3 of the logic section 1 at the high level, preventing output logic from becoming indefinite.

Here, the voltage to be applied to the gate electrode of the pull-up transistor 3 is raised by the pull-up control section 4; thus the voltage is accordingly higher, compared to when a low level MT enable signal MTE is inputted to the gate electrode. Consequently, the gate leak current can be suppressed.

The number of transistors in the pull-up control section increases, compared to the first embodiment. However, in the first embodiment, the potential inputted to the gate electrode of the pull-up transistor 3 during standby depends on device characteristics of the PMOS transistor of the pull-up control section 4, so the potential is adversely affected by a variation of manufacturing process. In contrast, in the present embodiment, the above potential does not depend on the device characteristics of the transistor and is determined by VSSV, so the output MTEV of the pull-up control section 4 is stabilized.

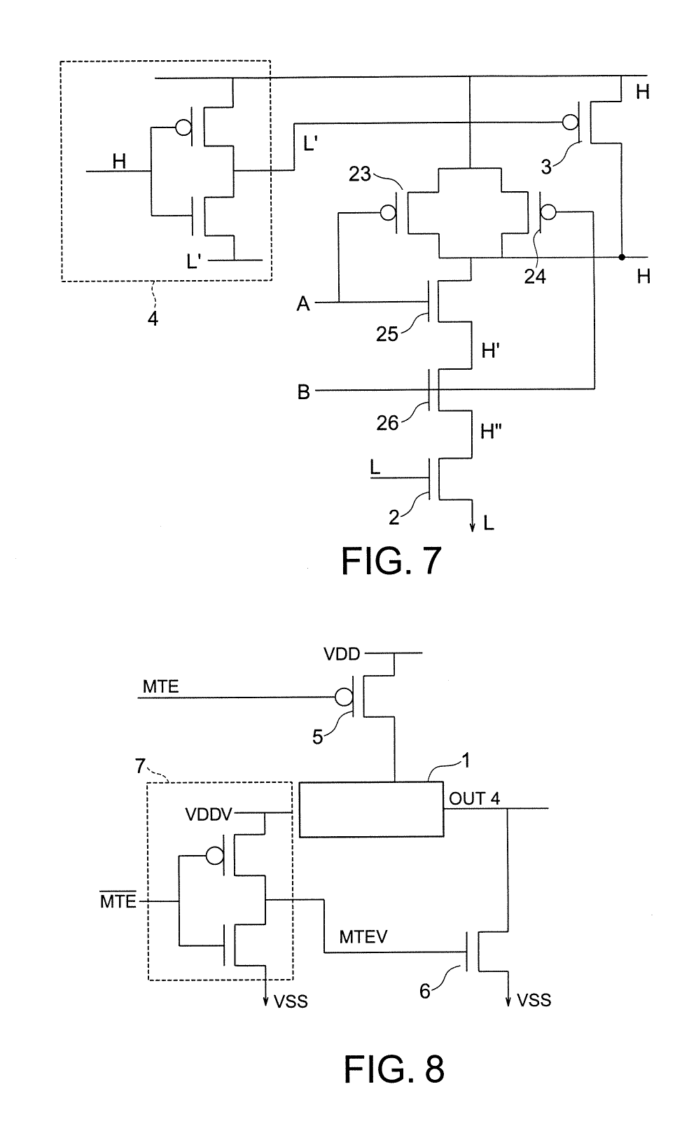

FIG. 7 is a view illustrating output levels of each transistor in a case where the logic section 1 is constituted of a NAND circuit, and a MT enable signal MTE of a low level (L) is inputted to the gate electrode of the switch transistor 2 and thus the switch transistor 2 turns off, changing the logic section 1 to a standby state. Here, assume that ground potential VSS=L<L′=VSSV<<H″<H′<H=power source potential VDD. L′ is sufficient to turn on the pull-up transistor 3 of a threshold voltage Vth3 (L<L′<VDD−|Vth3|). Since a high level signal is inputted to the pull-up control section 4, the output potential thereof changes to L′. This potential is inputted to the gate electrode of the pull-up transistor 3 and thus the pull-up transistor 3 turns on, whereby the output of the logic section 1 is fixed at the high level H, preventing output logic from becoming indefinite. At this time, the voltage to be applied to the gate electrode of the pull-up transistor 3 is raised by L′−L, compared to when an MT enable signal MTE of a low level (L) is inputted to the gate electrode. Consequently, the gate leak current of the pull-up transistor 3 can be suppressed.

As described above, according to the semiconductor integrated circuit of the second embodiment, the gate leak current flowing in the pull-up transistor while the gate circuit is in a standby state can be suppressed.

FIG. 8 illustrates a circuit configuration of a SMT gate circuit being a semiconductor integrated circuit according to a variation of the above described second embodiment. The SMT gate circuit includes a logic section 1, a switch transistor 5, a pull-down transistor 6 and a pull-down control section 7.

The logic section 1 is constituted of a low threshold transistor. The switch transistor 5 is a PMOS transistor, arranged between the logic section 1 and a power source VDD, and turned on/off by an MT enable signal MTE inputted to the gate electrode thereof. The pull-down transistor 6 is an NMOS transistor which turns on when the switch transistor 5 turns off and thereby fixes the output of the logic section 1 at a low level so as to prevent output logic from becoming indefinite. The threshold of the switch transistor 5 and pull-down transistor 6 is higher than that of the transistor constituting the logic section 1.

The pull-down control section 7 has an inverter circuit arranged between a ground VSS and a reference voltage line VDDV, and receives an inverted signal of an MT enable signal MTE. An output MTEV thereof is inputted to the gate electrode of the pull-down transistor 6. VDDV is lower than the power source potential VDD and is a sufficient potential to turn on the pull-down transistor 6 of a threshold Vth6 (Vth6<VDDV<VDD). This reference voltage line VDDV is arranged in addition to the power source line.

When a low level MT enable signal MTE is inputted to the gate electrode of the switch transistor 5, the switch transistor 5 turns on, and thus the power source voltage is applied to the logic section 1, changing the logic section 1 to an operating state. At this time, the pull-down transistor 6 is in an off state, so an output OUT4 of the logic section 1 is outputted from an output terminal thereof (not illustrated).

Meanwhile, when a high level MT enable signal MTE is inputted to the gate electrode of the switch transistor 5, the switch transistor 5 turns off, and thus the leak path of the logic section 1 is cut off, changing the logic section 1 to a standby state. When a low level signal is inputted to the pull-down control section 7, the output MTEV thereof changes to VDDV. When this output MTEV is inputted to the gate electrode of the pull-down transistor 6, the pull-down transistor 6 turns on and thereby fixes the output of the logic section 1 at the low level, preventing output logic from becoming indefinite.

Here, the voltage to be applied to the gate electrode of the pull-down transistor 6 is lowered by the pull-down control section 7; thus the voltage is accordingly lower, compared to when a high level MT enable signal MTE is inputted to the gate electrode. Consequently, the gate leak current flowing in the pull-down transistor 6 can be reduced.

Using the above described configuration, the gate leak current flowing in the pull-down transistor while the gate circuit is in a standby state can be suppressed.

### Third Embodiment

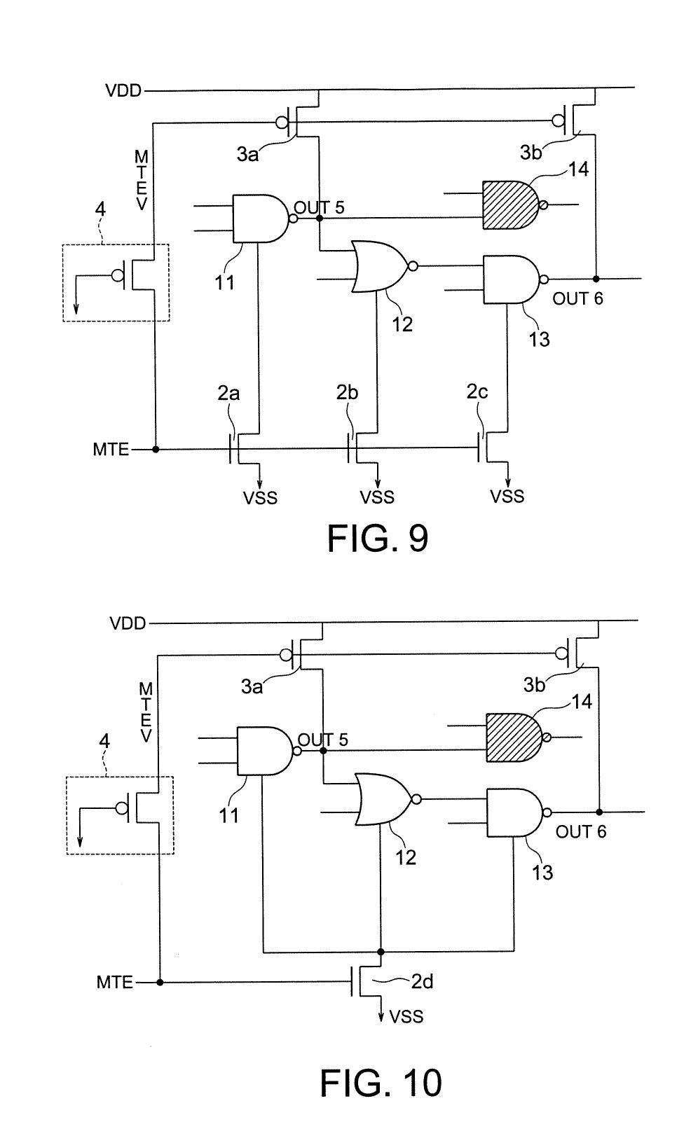

FIG. 9 illustrates an exemplary circuit configuration of a semiconductor integrated circuit according to a third embodiment of the present invention. In the present embodiment, as an SMT gate circuit, there is used the SMT gate circuit described above in the first or second embodiment. SMT gate circuits 11 to 13 have switch transistors 2a to 2c, respectively, for performing switching of supplying a ground voltage to a logic section. The switch transistors 2a to 2c are turned on/off by an MT enable signal MTE.

Here, in the output of that SMT gate circuit, such as the SMT gate circuit 12, which has the output thereof inputted only to an SMT gate circuit, there is arranged no pull-up transistor. In the SMT gate circuit 11 having the output thereof inputted to a gate circuit 14 having no switch transistor, there is arranged a pull-up transistor 3a. In the output of the SMT gate circuit 13, there is also arranged a pull-up transistor 3b.

When a low level MT enable signal MTE is inputted to the gate electrodes of the switch transistors 2a to 2c, the switch transistors 2a to 2c turn off, and thus the logic sections of the SMT gate circuits 11 to 13 change to a standby state. When the low level MT enable signal MTE is inputted to the pull-up control section 4, the output MTEV thereof changes to a potential higher than the low level. This output MTEV is a potential higher than the low level, but is sufficient to turn on the pull-up transistors 3a and 3b of a threshold Vth3 (VSS<MTEV<VDD−|Vth3|). Accordingly, when the output MTE is inputted to the gate electrodes of the pull-up transistors 3a and 3b, the pull-up transistors 3a and 3b turn on and thereby fixes the logic section outputs OUT5 and OUT6 at a high level, preventing output logic from becoming indefinite. The voltage to be applied to the gate electrodes of the pull-up transistors 3a and 3b is raised by the pull-up control section 4; thus the voltage is accordingly higher, compared to when a low level MT enable signal MTE is inputted to the gate electrodes. Consequently, the gate leak current flowing in the pull-up transistors 3a and 3b can be suppressed.

Here, the output logic of the SMT gate circuit 12 having no pull-up transistor arranged in the output thereof becomes indefinite. However, the output of this SMT gate circuit 12 is inputted to the SMT gate circuit 13 having the leak path cut off by the switch transistor 2c, so a problem of increased leak current does not occur. Also, the number of pull-up transistors can be minimized, thus making it possible to suppress the increase of layout area.

As described above, according to the semiconductor integrated circuit of the third embodiment, the gate leak current flowing in the pull-up transistor while the gate circuit is in a standby state can be suppressed, and further the number of pull-up transistors can be reduced.

### Fourth Embodiment

FIG. 10 illustrates an exemplary circuit configuration of a semiconductor integrated circuit according to a fourth embodiment of the present invention. In this configuration, the respective switch transistors 2a to 2c of the SMT gate circuits 11 to 13 in the semiconductor integrated circuit illustrated in FIG. 9 is replaced with one switch transistor 2d in a shared manner.

When a low level MT enable signal MTE is inputted to the gate electrode of the switch transistor 2d, the switch transistor 2d turns off, and thus the leak paths of the SMT gate circuits 11 to 13 are cut off, changing the respective logic sections to a standby state. Inputted to the gate electrodes of pull-up transistors 3a and 3b connected to the respective outputs of the SMT gate circuits 11 and 13 is an output MTEV of a pull-up control section 4, which is a potential higher than the low level and at the same time, lower than the threshold voltage of pull-up transistors 3a and 3b. Then the pull-up transistors 3a and 3b turn on and thereby fix the logic section outputs OUT5 and OUT6 at a high level, preventing output logic from becoming indefinite.

The voltage to be applied to the gate electrodes of the pull-up transistors 3a and 3b is raised by the pull-up control section 4; thus the voltage is accordingly higher, compared to when a low level MT enable signal MTE is inputted to the gate electrodes. Consequently, the gate leak current of the pull-up transistors 3a and 3b can be suppressed. Also, since the switch transistors of a plurality of the SMT gate circuits are replaced by the one switch transistor in a shared manner, the number of switch transistors can be reduced, compared to the semiconductor integrated circuit according to the third embodiment illustrated in FIG. 9. Consequently, the increase of layout area does not occur and also the circuit structure can be simplified.

As described above, according to the semiconductor integrated circuit of the fourth embodiment, the gate leak current flowing in the pull-up transistor while the gate circuit is in a standby state can be suppressed, and further the number of pull-up transistors and switch transistors can be reduced.

In the third and fourth embodiments described above, the following configuration may be used. That is, the gate circuits 11 to 13 located on the critical path are constituted of the SMT gate circuits described in the first or second embodiments; and the gate circuit 14 located on the non-critical path is constituted of a transistor having a gate oxide film thickness larger than that of the transistor constituting the above SMT gate circuit, or constituted of a transistor using high-permittivity gate insulating film as the gate oxide film.

The gate leak current is current flowing through the insulating film due to the quantum tunneling effect when the gate oxide film is slimmed down and thus insulation properties are reduced. Accordingly, it is effective to increase the thickness of gate oxide film in reducing the gate leak current; thus the gate leak current can be suppressed by increasing the thickness of gate oxide film or by using a high-permittivity material as the gate oxide film.

Consequently, when the SMT gate circuit described in the first or second embodiment is used, the gate leak current in the gate circuits 11 to 13 located on the critical path and the gate leak current of the pull-up transistors 3a and 3b can be reduced. Also, when the gate circuit 14 located on the non-critical path is constituted of a transistor having a large gate oxide film thickness or of a transistor using a high-permittivity material as the gate oxide film, the gate leak current in the gate circuit located on the non-critical path can be reduced. The number of non-critical paths is larger in actual circuits; thus, when such configuration is used, the effect of reducing the leak current can be enhanced.

### Fifth Embodiment

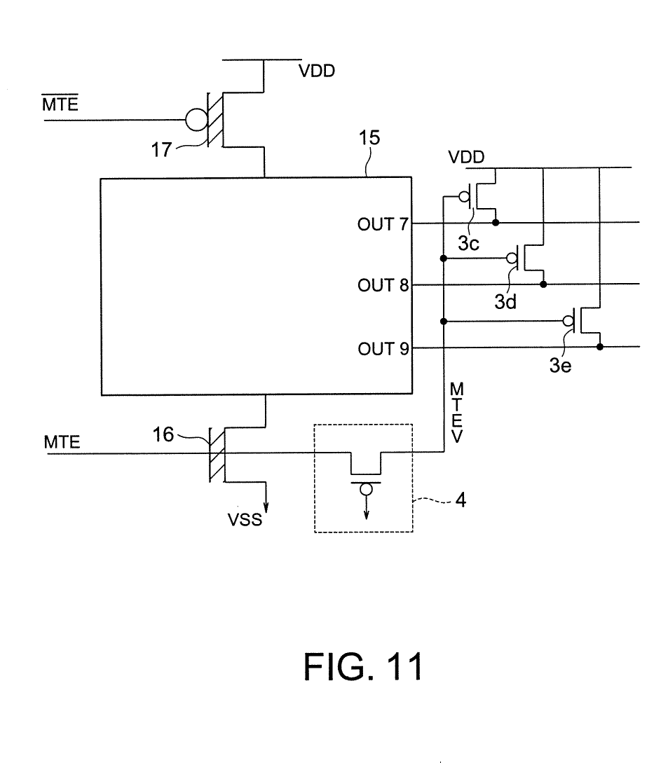

FIG. 11 illustrates a circuit configuration of a semiconductor integrated circuit according to a fifth embodiment of the present invention. The semiconductor integrated circuit includes a circuit block 15, switch transistors 16 and 17, a pull-up control section 4 and pull-up transistors 3c to 3e. The pull-up transistors 3c to 3e are provided for each of plural outputs OUT7 to OUT9 of the circuit block 15.

The switch transistor 16 is connected between the circuit block 15 and the ground; and supplying of a ground voltage VSS to the circuit block 15 is controlled by an MT enable signal MTE inputted to the gate electrode of the switch transistor 16. The switch transistor 17 is connected between the circuit block 15 and a power source line; and supplying of a power source voltage VDD to the circuit block 15 is controlled by an inverted signal of an MT enable signal MTE inputted to the gate electrode of the switch transistor 17. The pull-up control section 4 has a PMOS transistor which has the gate electrode fixed at the ground voltage and which receives an MT enable signal MTE; and an output MTEV thereof is inputted to the gate electrodes of the pull-up transistors 3c to 3e.

When a low level MT enable signal MTE is inputted to the gate electrode of the switch transistor 16 and an inverted signal of the above MT enable signal MTE is inputted to the gate electrode of the switch transistor 17, both the switch transistors 16 and 17 turn off and thus the leak path extending from the power source line to the ground line is cut off, changing the circuit block 15 to an standby state. Inputted to the pull-up control section 4 is a low level MT enable signal MTE, and thus the output MTEV changes to a potential higher than the low level. This output MTEV is a potential higher than the low level and sufficient to turn on the pull-up transistors 3c to 3e of a threshold Vth3 (VSS<MTEV<VDD−|Vth3|).

This output MTEV is inputted to the gate electrodes of the pull-up transistors 3c to 3e and thus the pull-up transistors 3c to 3e turn on. Accordingly, a plurality of the outputs OUT7 to OUT9 of the circuit block 15 are each fixed at a high level, preventing output logic from becoming indefinite. The voltage to be applied to the gate electrodes of the pull-up transistors 3c to 3e is raised by the pull-up control section 4; thus the voltage is accordingly higher, compared to when a low level MT enable signal MTE is inputted thereto. Consequently, the gate leak current of the pull-up transistors during standby can be suppressed.

Therefore, according to the semiconductor integrated circuit of the fifth embodiment, the gate leak current flowing in the pull-up transistor while the gate circuit is in a standby state can be suppressed.

According to the first to fifth embodiments, the leak current flowing in the pull-up transistor while the gate circuit is in a standby state can be reduced.

The number of outputs of the circuit block 15 is not limited to three, and may be one, two, or four or more.

Also, a configuration may be used in which the pull-up transistor is replaced with a pull-down transistor and the pull-up control section is replaced with a pull-down control section which has an NMOS transistor having the gate electrode thereof connected to the power source line. Also, only one of the switch transistors may be arranged; and when only the switch transistor 16 is arranged, a pull-up transistor and pull-up control section are used; and when only the switch transistor 17 is arranged, a pull-down transistor and pull-down control section are used.

What is claimed is:

1. A semiconductor integrated circuit comprising:
a logic section having a plurality of first transistors;
a second transistor, having source and drain electrodes connected between a first reference voltage line and a first reference voltage line side terminal of the logic section, and having a gate electrode to which a control signal for controlling whether to supply a power source voltage to the logic section is inputted;
a third transistor having a source and drain electrode connected between an output terminal of the logic section and a second reference voltage line, wherein the third transistor turns off when the second transistor turns on, and turns on when the second transistor turns off; and
a control section, connected to a gate electrode of the third transistor, and performing on/off control of the third transistor.

2. The semiconductor integrated circuit according to claim 1, wherein the control section has a fourth transistor, having a source and drain electrode connected between the gate electrode of the second transistor and the gate electrode of the third transistor, and having a gate electrode connected to the first reference voltage line.

3. The semiconductor integrated circuit according to claim 2,
wherein:
the first reference voltage line is a ground line and the second reference voltage line is a power source line; and
the fourth transistor is a PMOS transistor.

4. The semiconductor integrated circuit according to claim 3, wherein the second transistor is an NMOS transistor and the third transistor is a PMOS transistor.

5. The semiconductor integrated circuit according to claim 2,
wherein:
the first reference voltage line is a power source line and the second reference voltage line is a ground line; and
the fourth transistor is an NMOS transistor.

6. The semiconductor integrated circuit according to claim 5,
wherein the second transistor is a PMOS transistor and the third transistor is an NMOS transistor.

7. The semiconductor integrated circuit according to claim 1, wherein the control section has an inverter circuit, connected between the second reference voltage line and a third reference voltage line, and receiving an inverted signal of the control signal, and having an output terminal connected to the gate electrode of the third transistor.

8. The semiconductor integrated circuit according to claim 7,
wherein:
the first reference voltage line is a ground line and the second reference voltage line is a power source line; and
the second transistor is an NMOS transistor and the third transistor is a PMOS transistor.

9. The semiconductor integrated circuit according to claim 8, wherein the potential of the third reference voltage line is higher than a ground potential, and capable of turning on the third transistor.

10. The semiconductor integrated circuit according to claim 7,
wherein:
the first reference voltage line is a power source line and the second reference voltage line is a ground line; and
the second transistor is a PMOS transistor and the third transistor is an NMOS transistor.

11. The semiconductor integrated circuit according to claim 10, wherein the potential of the third reference voltage line is lower than the power source potential, and capable of turning on the third transistor.

12. The semiconductor integrated circuit according to claim 1,
wherein the semiconductor integrated circuit has a plurality of the third transistors, the logic section has a plurality of the output terminals, and source and drain electrodes of each of the third transistors are connected between the second reference voltage line and the corresponding output terminal.

13. A semiconductor integrated circuit comprising:
first and second gate circuits with switches each having:
a logic section having a plurality of first transistors; and
a second transistor, having a source and drain electrode connected between a first reference voltage line and a first reference voltage line side terminal of the logic section, and having a gate electrode to which a control signal for controlling whether to supply a power source voltage to the logic section is inputted,
a third transistor having a source and drain electrode connected between an output terminal of the logic section of the first gate circuit with a switch and a second reference voltage line; and
a control section, connected to a gate electrode of the third transistor, and performing on/off control of the third transistor,
wherein an output terminal of the second gate circuit with a switch and an input terminal of the first gate circuit with a switch are connected to each other.

14. The semiconductor integrated circuit according to claim 13, wherein the control section has a fourth transistor, having a source and drain electrode connected between the gate electrode of the second transistor and the gate electrode of the third transistor, and having a gate electrode connected to the first reference voltage line.

15. The semiconductor integrated circuit according to claim 14,
wherein:
the first reference voltage line is a ground line and the second reference voltage line is a power source line; and
the second transistor is an NMOS transistor and the third and fourth transistors are PMOS transistors.

16. The semiconductor integrated circuit according to claim 14,
wherein:
the first reference voltage line is a power source line and the second reference voltage line is a ground line; and
the second transistor is a PMOS transistor and the third and fourth transistors are NMOS transistors.

17. A semiconductor integrated circuit comprising:
first and second gate circuits each having:
a logic section having a plurality of first transistors; and
a second transistor having source and drain electrode connected between an output terminal of the logic section and a first reference voltage line,
a third transistor, having source and drain electrode connected between a second reference voltage line and second reference voltage line side terminals of the first and second gate circuits, and having a gate electrode to which a control signal for controlling whether to supply a power source voltage to the first and second gate circuits is inputted; and
a control section, connected to a gate electrode of the second transistor, and performing on/off control of the second transistor so that the second transistor is turned off when the third transistor turns on, and turned on when the third transistor turns off.

18. The semiconductor integrated circuit according to claim 17, wherein the control section has a fourth transistor, having a source and drain electrode connected between the gate electrode of the second transistor and the gate electrode of the third transistor, and having a gate electrode connected to the second reference voltage line.

19. The semiconductor integrated circuit according to claim 18,
wherein:
the first reference voltage line is a power source line and the second reference voltage line is a ground line; and
the second and fourth transistors are PMOS transistors and the third transistor is an NMOS transistor.

20. The semiconductor integrated circuit according to claim 18,
wherein:
the first reference voltage line is a ground line and the second reference voltage line is a power source line; and the second and fourth transistors are NMOS transistors and the third transistor is a PMOS transistor.
